(19) United States
(12) Patent Application Publication
(10) Pub. No.: US 2014/0165911 A1
(43) Pub. Date: Jun. 19, 2014

(54) APPARATUS FOR PROVIDING PLASMA TO A PROCESS CHAMBER

(71) Applicant: APPLIED MATERIALS, INC., Santa Clara, CA (US)

(72) Inventors: CHIEN-TEH KAO, SUNNYVALE, CA (US); HYMAN W.H. LAM, SAN JOSE, CA (US); NICHOLAS R. DENNY, SANTA CLARA, CA (US); DAVID T. OR, SANTA CLARA, CA (US); MEI CHANG, SARATOGA, CA (US); MURALI K. NARASIMHAN, SAN JOSE, CA (US)

(73) Assignee: APPLIED MATERIALS, INC., SANTA CLARA, CA (US)

(21) Appl. No.: 13/715,281

(22) Filed: Dec. 14, 2012

(51) Int. Cl. H01J 37/32

(52) U.S. Cl. CPC H01J 37/32009
USPC 118/723 E; 313/231.41

(57) ABSTRACT

Embodiments of apparatus for providing plasma to a process chamber are provided. In some embodiments, an apparatus may include a first ground plate; an electrode disposed beneath and spaced apart from the first ground plate by a first electrical insulator to define a first gap between the first ground plate and the electrode; a second ground plate disposed beneath and spaced apart from the electrode by a second electrical insulator to define a second gap between the electrode and the second ground plate; a gas inlet to provide a process gas to the first gap; a plurality of through holes disposed through the electrode coupling the first gap to the second gap; and a plurality of first gas outlet holes disposed through the second ground plate to fluidly couple the second gap to an area beneath the second plate.

### FIELD

Embodiments of the present invention generally relate to semiconductor processing equipment.

### BACKGROUND

Some conventional substrate process chambers utilize a plasma source having one or more electrodes configured to form a plasma from a process gas prior to introducing the process gas into the process chamber. However, the inventors have observed that in such plasma sources electrical arcing may occur between a grounded gas supply line and the electrically charged electrode. The inventors have further observed that such electrical arcing typically produces a plasma discharge (e.g., a parasitic plasma) that may cause damage to process chamber components (e.g., gas inlets, electrodes, or the like) and/or cause particle formation within the process chamber that can settle on the substrate during processing, thereby producing undesired process results.

Therefore, the inventors have provided improved apparatus for providing plasma to a process chamber.

### SUMMARY

Embodiments of apparatus for providing plasma to a process chamber are provided. In some embodiments, an apparatus may include a first ground plate; an electrode disposed beneath and spaced apart from the first ground plate by a first electrical insulator disposed between the first ground plate and the electrode to define a first gap between the first ground plate and the electrode; a second ground plate disposed beneath and spaced apart from the electrode by a second electrical insulator disposed between the electrode and the second ground plate to define a second gap between the electrode and the second ground plate; a gas inlet to provide a process gas to the first gap; a plurality of through holes disposed through the electrode coupling the first gap to the second gap; and a plurality of first gas outlet holes disposed through the second ground plate to fluidly couple the second gap to an area beneath the second plate.

In some embodiments, a process chamber may include a chamber body having a substrate support disposed in an inner volume of the process chamber; a lid disposed atop the chamber body, the lid comprising a plasma source. The plasma source may include a first ground plate; an electrode disposed beneath and spaced apart from the first ground plate by a first electrical insulator to define a first gap between the first ground plate and the electrode; a second ground plate disposed beneath and spaced apart from the electrode by a second electrical insulator to define a second gap between the electrode and the second ground plate; a gas inlet to provide a process gas to the first gap; a plurality of through holes disposed through the electrode coupling the first gap to the second gap; and a plurality of first gas outlet holes disposed through the second ground plate to fluidly couple the second gap to an area beneath the second plate.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic side view of an apparatus for providing a plasma to a process chamber in accordance with some embodiments of the present invention.

FIG. 2 depicts a schematic side view of an apparatus for providing a plasma to a process chamber in accordance with some embodiments of the present invention.

FIG. 3 depicts a schematic side view of an apparatus for providing a plasma to a process chamber in accordance with some embodiments of the present invention.

FIG. 4 depicts a process chamber suitable for use with an apparatus for providing a plasma to a process chamber in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of apparatus for providing plasma to a process chamber that may reduce or eliminate voltage arcing or the formation of a parasitic plasma are provided herein.

The inventors have observed that conventional plasma sources typically utilize a grounded gas supply line to provide a process gas to an electrically charged electrode. However, due to a voltage drop between the electrode and the gas supply line, electrical arcing may occur proximate a point where the gas supply line feeds the process gas to the electrode. This electrical arcing produces a plasma discharge (e.g., a parasitic plasma) that may cause damage to the process chamber components (e.g., gas inlets, electrodes, or the like) and/or cause particle formation within the process chamber that can settle on the substrate during processing, thereby producing undesired process results.

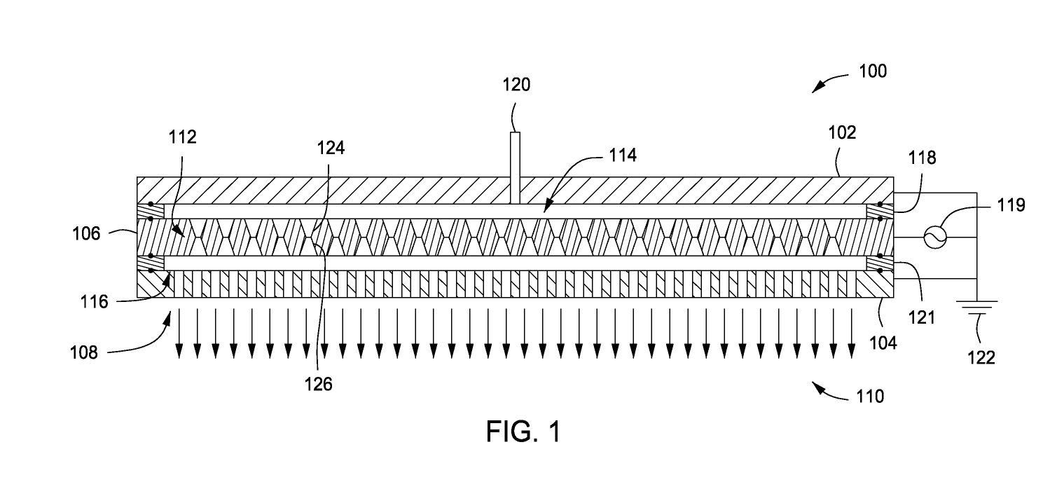

Accordingly, in some embodiments, the apparatus for providing a plasma to a process chamber (plasma source) 100 may generally comprise a first ground plate 102, a second ground plate 104 and an electrode 106, such as shown in FIG. 1. In some embodiments, the first ground plate 102 and the second ground plate 104 may be coupled to a common ground 122.

The first ground plate 102 and the second ground plate 104 may be fabricated from any process compatible conductive material. For example, in some embodiments, the first ground plate 102 and/or the second ground plate 104 may be fabricated from a metal or metal alloy, for example, such as aluminum, nickel coated aluminum, steel, stainless steel, iron, nickel, chromium, alloys thereof, combinations thereof, or the like. In some embodiments, each of the first ground plate 102 and the second ground plate 104 may be fabricated from the same, or in some embodiments, a different material.

A first plenum is disposed between the first ground plate 102 and the electrode 106. For example, in some embodiments, a first electrical insulator 118 may be disposed between the first ground plate 102 and the electrode 106 to form a first gap 114 (e.g., a first plenum) between the first ground plate 102 and the electrode 106. A gas inlet 120 may be disposed through the first ground plate 102 to provide one or more process gases to the first gap 114 of the plasma source 100. The first gap 114 provides a cavity to allow for the ignition of the process gas to form the plasma.

The electrode 106 comprises a plurality of through holes 112 that fluidly couple the first gap 114 to a second plenum disposed between the electrode 106 and the second ground plate 104 to allow for the process gas and/or the plasma formed in the first gap 114 to pass through the electrode 106 and into the second plenum. For example, in some embodiments, a second electrical insulator 121 may be disposed between the electrode 106 and the second ground plate 104 to form a second gap 116 (e.g., a second plenum) between the electrode 106 and the second ground plate 104. The second ground plate 104 includes one or more gas outlet holes 108 (e.g., through holes) to allow the activated species (e.g., radicals) generated in the plasma to flow from the plasma source 100 (flow indicated by arrows 110) to, for example, a processing volume of a process chamber. The second gap 116 provides a second cavity to allow for the ignition of the process gas to form the plasma and to further allow for the accumulation of the plasma to facilitate dispersion of the plasma species via the gas outlet holes 108. The inventors believe that providing multiple cavities (e.g., the first gap 114 and the second gap 116) allows for the plasma to be formed in each of the cavities, thereby providing multiple excitation stages of the plasma to facilitate enhanced radical generation, as compared to conventional plasma sources that may utilize a single cavity to form the plasma.

The first electrical insulator 118 and the second electrical insulator 121 electrically isolate the first ground plate 102 and the second ground plate 104 from the electrode 106. The first electrical insulator 118 and the second electrical insulator 121 may comprise any process compatible electrically insulating material. For example, in some embodiments, the first electrical insulator 118 and the second electrical insulator 121 may be fabricated from quartz (SiO₂), a sintered ceramic such as aluminum oxide (Al₂O₃) or silicon nitride (SiN), or a single crystal sapphire (Al₂O₃).

The inventors have observed that by providing the first ground plate 102 and the second ground plate 104 the electrical potential at the gas inlet 120 and gas outlet holes 108 is reduced or eliminated, thereby advantageously eliminating electrical arcing and the formation of a parasitic plasma proximate the gas inlet 120 and gas outlet holes 108. By eliminating the electrical arcing and the formation of the parasitic plasma, the above discussed plasma induced damage to the plasma source and particle formation may be reduced or eliminated.

A power supply 119 may be coupled to the electrode 106 to provide power to the electrode facilitate ignition of the process gas to form the plasma. The power supply 119 may be any type of power supply suitable to provide sufficient power to ignite the process gas, for example such as an RF power supply. In embodiments where the power supply 119 is an RF power supply, the power supply 119 may provide RF power at a frequency range of less than about 100 kHz to about 100 MHz.

The electrode 106 may be fabricated from any process compatible conductive material. For example, in some embodiments, the electrode may be fabricated from a metal or metal alloy, such as aluminum, steel, stainless steel, iron, nickel, chromium, alloys thereof, combinations thereof, or the like.

In some embodiments, the plurality of through holes 112 may comprise one or more conical shapes. For example, in some embodiments, each of the plurality of through holes 112 may comprise an upper cone 124 coupled to a lower cone 126 proximate a vertex of each of the upper cone 124 and the lower cone 126, such as shown in FIG. 1. The inventors have observed that conically shaped through holes 112 may facilitate more uniform ignition of the process gas, thereby producing uniform plasma. In some embodiments, the conically shaped through holes 112 may offset inconsistencies in the plasma ignition due to, for example, a non-uniform size of the first gap 114 and/or second gap 116 due to the first ground plate 102 or second ground plate 104 being non-parallel with the electrode 106. In addition, the inventors have observed that conically shaped through holes 112 may facilitate ignition of a higher plasma density, thereby providing an increased radical generation within the plasma.

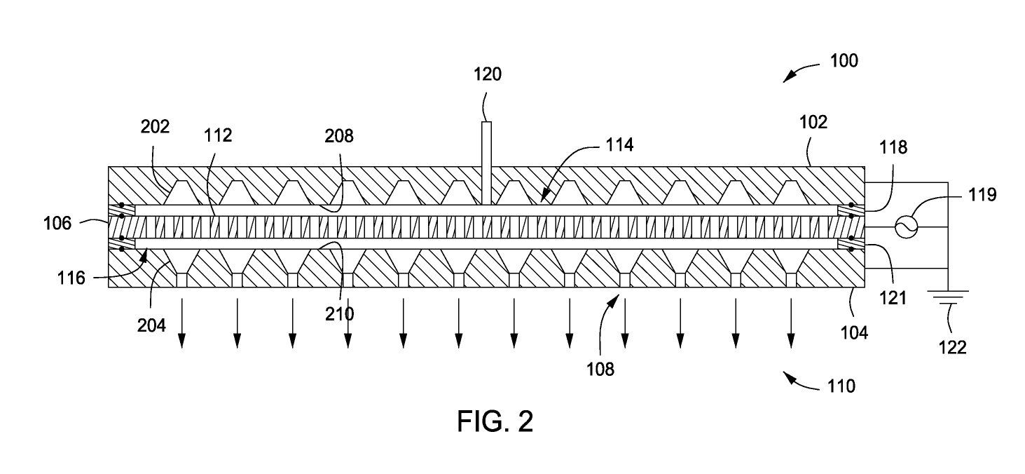

Alternatively, or in combination, for example as depicted in FIG. 2, in some embodiments, at least one of the first ground plate 102 or the second ground plate 104 may have a plurality of conically shaped cavities 202, 204 formed in the inner facing surfaces 208, 210 of the first ground 102 and the second ground plate 104. In such embodiments, the gas outlet holes 108 may be fluidly coupled to the conically shaped cavities 204 formed in the second ground plate 104. When present, the conically shaped cavities 202 perform the same function as the through holes 112 having a conical shape, as described above. In such embodiments, the through holes 112 of the electrode 106 may be cylindrical, such as shown in FIG. 2, or conical, as shown in FIG. 1.

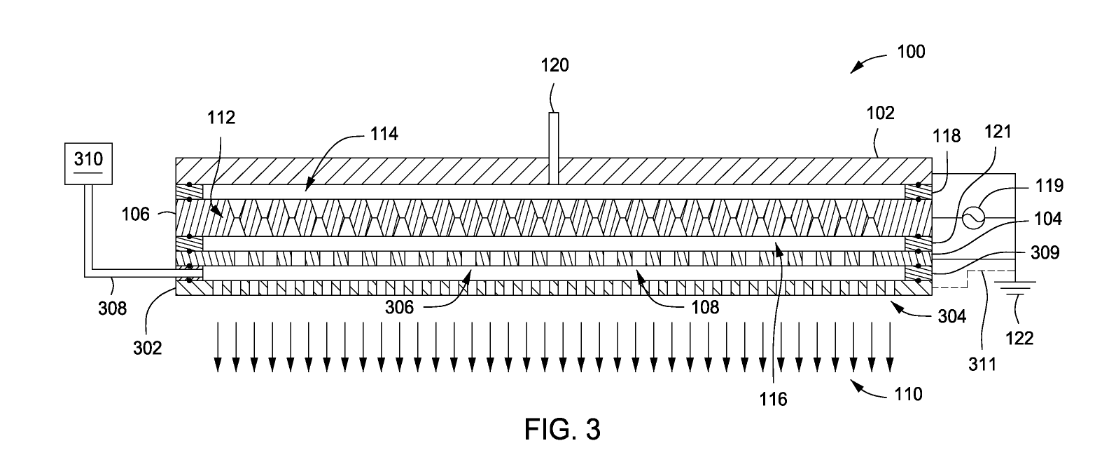

Referring to FIG. 3, in some embodiments, the plasma source 100 may comprise a third ground plate 302 coupled to the second ground plate 104. The third ground plate 302 may be fabricated from a metal or metal alloy, for example, such as aluminum, nickel coated aluminum, steel, stainless steel, iron, nickel, chromium, alloys thereof, combinations thereof, or the like. In some embodiments, the third ground plate 302 may be grounded via a separate coupling to the common ground 122 (as shown in phantom at 311), or via an electrical coupling to the second ground plate 104. For example, in some embodiments, the third ground plate 302 may be electrically coupled to the second ground plate 104 via a conductive ring 309 disposed between the second ground plate 104 and the third ground plate 302, as shown in FIG. 3. Although described as separate components, the conductive ring 309 may be integrally formed with either the second ground plate 104 or the third ground plate 302.

In some embodiments, the third ground plate 302 may be coupled to the second ground plate 104 such that a third gap 306 (e.g., a third plenum) may be formed between the second ground plate 104 and the third ground plate 302. A gas inlet 308 may be coupled to the third gap 306 to provide a process gas to the third gap 306 provided by, for example, a gas source 310, to facilitate a desired process. The process gas provided by the gas inlet 308 to the third gap 306 may be any type of gas required by the desired process, for example, such as a carrier gas, purge gas, cleaning gas, reactive gas, or the like. Due to the location of the third gap 306 with respect to the electrode 106, gas provided to the third gap 306 via the third gas inlet 308 advantageously will not be energized into a plasma state via the power supply 119. As such, in some embodiments, the concentration of active or energized species flowing into the process chamber from the plasma source may further be controlled via control of the amount of gas added via the third gas inlet 308.

The third ground plate 302 includes a plurality of gas outlet holes 304 to allow the plasma and/or process gas to flow from the plasma source 100 (flow indicated by arrows 110) to, for example, a processing volume of a process chamber. In some embodiments, the gas outlet holes 304 of the third ground plate 302 may have a diameter that is smaller than the gas outlet holes 108 of the second plate 106. Providing smaller the gas outlet holes 304 may allow the third ground plate 302 to function as a filter to prevent undesired components of the plasma from entering the process chamber. For example, in some embodiments, the gas outlet holes 304 of the third ground plate 302 may prevent charged ions that would cause damage to a substrate from entering the process chamber while allowing neutral radicals to pass into the process chamber. In other embodiments, the gas outlet holes 304 of the third ground plate 302 may have a diameter that is the same as or larger than the gas outlet holes 108 of the second plate 106.

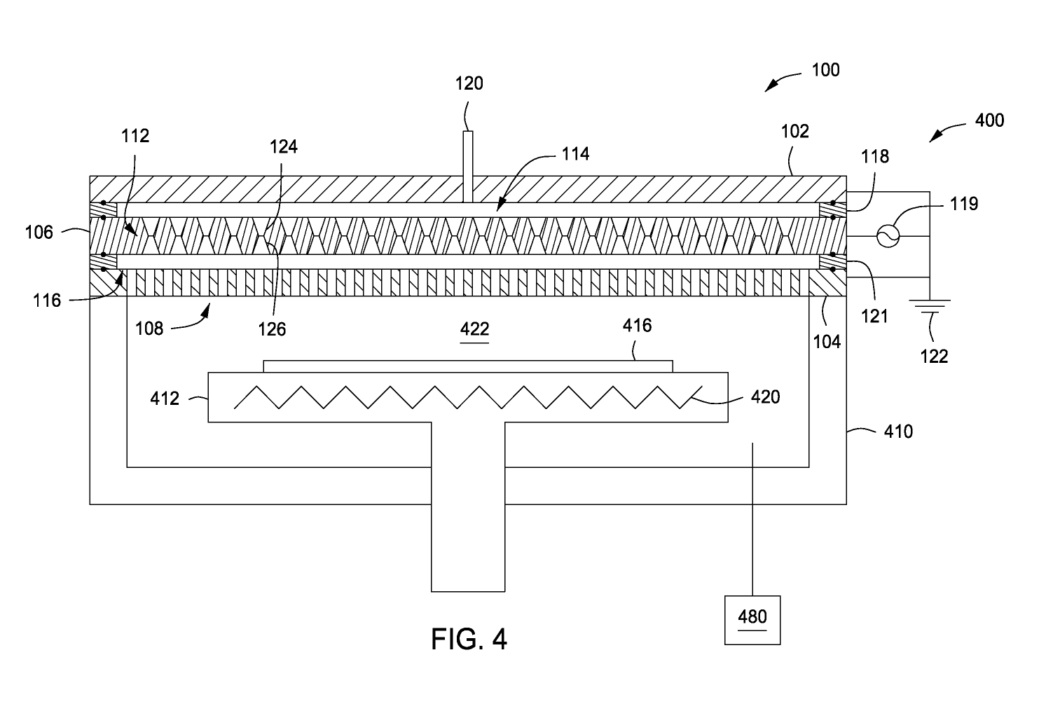

The plasma source 100 may be a standalone apparatus configured to produce a plasma that is subsequently provided to a process chamber (e.g., a remote plasma source), or in some embodiments, the plasma source 100 may be integrated into a process chamber. For example, the plasma source 100 may be integrated into a process chamber lid, for example such as in process chamber 400 depicted in FIG. 4.

Referring to FIG. 4, the process chamber 400 may be any process chamber suitable for plasma enhanced semiconductor processing, for example, such as a process chamber configured to perform a plasma assisted chemical vapor deposition (CVD) or an atomic layer deposition (ALD) process. Exemplary process chambers may include the ENDURA®, PRODUCER® or CENTURA® platform process chambers, or other process chambers, available from Applied Materials, Inc. of Santa Clara, Calif. Other suitable process chambers may similarly be used.

In some embodiments, the process chamber 400 may generally comprise a chamber body 410 and a substrate support 412 disposed within the chamber body 410. In some embodiments, the inventive plasma source 100 is disposed atop the chamber body and is integrated with, or functions as, a chamber lid or a portion thereof.

The substrate support 412 is configured to support one or more substrates 416 in a processing volume 422 defined by the chamber body 410 and the plasma source 100 and/or process chamber lid. In some embodiments, the substrate support 412 may include a heater 420 adapted to heat the one or more substrates 416, or fluid cooling channel (not shown) adapted to heat the one or more substrates 416, to a temperature required by the process being performed.

In some embodiments, the process chamber 400 includes a vacuum pump 480 to pump out the processing volume 422 to obtain and/or maintain a desired pressure in the processing volume 422. During processing, the vacuum pump 480 provides a negative pressure in the processing volume 422 relative to the second gap 116 of the plasma source 100, thus allowing the species in the second gap 116 to flow to the processing volume 422.

Thus, embodiments of an apparatus for providing plasma to a process chamber that may reduce or eliminate voltage arcing or the formation of a parasitic plasma have been provided herein. While the foregoing is directed to embodiments of the present invention, other and further embodiments of the invention may be devised without departing from the basic scope thereof.

1. An apparatus for providing a plasma to a process chamber, comprising:
a first ground plate;
an electrode disposed beneath and spaced apart from the first ground plate by a first electrical insulator to define a first gap between the first ground plate and the electrode;
a second ground plate disposed beneath and spaced apart from the electrode by a second electrical insulator to define a second gap between the electrode and the second ground plate;
a gas inlet to provide a process gas to the first gap;
a plurality of through holes disposed through the electrode coupling the first gap to the second gap; and
a plurality of first gas outlet holes disposed through the second ground plate to fluidly couple the second gap to an area beneath the second plate.

2. The apparatus of claim 1, wherein the first ground plate and the second ground plate are electrically coupled to a ground.

3. The apparatus of claim 1, wherein the apparatus is integrated into a lid of the process chamber.

4. The apparatus of claim 1, wherein the first ground plate comprises a gas inlet fluidly coupled to the first gap to provide a process gas to the first gap.

5. The apparatus of claim 1, wherein the plurality of through holes of the electrode comprise an upper cone coupled to a lower cone, wherein the upper cone is coupled to the lower cone proximate a vertex of each of the upper cone and the lower cone.

6. The apparatus of claim 1, wherein at least one of the first ground plate and the second ground plate has a conically shape cavity formed in a respective inner facing surface of the first ground plate and the second ground plate.

7. The apparatus of claim 1, further comprising a third ground plate coupled to the second plate, the third ground plate having a plurality of second gas outlet holes.

8. The apparatus of claim 7, wherein the plurality of second gas outlet holes have a diameter that is smaller than a diameter of the plurality of first gas outlet holes.

9. The apparatus of claim 7, further comprising:
a third gap disposed between the second ground plate and the third ground plate.

10. The apparatus of claim 9, further comprising:
a gas inlet fluidly coupled to the third gap to provide a process gas to the third gap.

11. The apparatus of claim 7, wherein the third ground plate is electrically coupled to a ground.

12. A process chamber comprising:
a chamber body having a substrate support disposed in an inner volume of the process chamber;
a lid disposed atop the chamber body, the lid comprising a plasma source, wherein the plasma source comprises:
a first ground plate;
an electrode disposed beneath and spaced apart from the first ground plate by a first electrical insulator to define a first gap between the first ground plate and the electrode;
a second ground plate disposed beneath and spaced apart from the electrode by a second electrical insulator to define a second gap between the electrode and the second ground plate;
a gas inlet to provide a process gas to the first gap;
a plurality of through holes disposed through the electrode coupling the first gap to the second gap; and
a plurality of first gas outlet holes disposed through the second ground plate to fluidly couple the second gap to an area beneath the second plate.

13. The process chamber of claim 12, wherein the first ground plate and the second ground plate are electrically coupled to a ground.

14. The process chamber of claim 12, wherein the first ground plate comprises a gas inlet fluidly coupled to the first gap to provide a process gas to the first gap.

15. The process chamber of claim 12, wherein the plurality of through holes of the electrode comprise an upper cone coupled to a lower cone, wherein the upper cone is coupled to the lower cone proximate a vertex of each of the upper cone and the lower cone.

16. The process chamber of claim 12, wherein at least one of the first ground plate and the second ground plate has a conically shape cavity formed in a respective inner facing surface of the first ground plate and the second ground plate.

17. The process chamber of claim 12, further comprising a third ground plate coupled to the second plate, the third ground plate having a plurality of second gas outlet holes.

18. The process chamber of claim 17, wherein the plurality of second gas outlet holes have a diameter that is smaller than a diameter of the plurality of first gas outlet holes.

19. The process chamber of claim 17, further comprising:
a third gap disposed between the second ground plate and the third ground plate.

20. The apparatus of claim 19, further comprising:
a gas inlet fluidly coupled to the third gap to provide a process gas to the third gap.
